(19) United States
(12) Patent Application Publication
(10) Pub. No.: US 2022/0182769 A1
(43) Pub. Date: Jun. 9, 2022

(54) MEMS MICROPHONE AND METHOD OF MANUFACTURING THE SAME

(71) Applicant: DB HITEK CO., LTD., Seoul (KR)

(72) Inventor: Dong Chun PARK, Incheon (KR)

(21) Appl. No.: 17/544,661

(22) Filed: Dec. 7, 2021

(30) Foreign Application Priority Data
Dec. 7, 2020 (KR) 10-2020-0169494

(51) Int. Cl. H04R 19/04; H04R 31/00

(52) U.S. Cl. CPC H04R 19/04; H04R 2201/003; H04R 31/003

(57) ABSTRACT

A MEMS microphone includes a substrate including a vibration area defining a cavity, a supporting area surrounding the vibration area, and a peripheral area surrounding the supporting area, a diaphragm disposed over the substrate to cover the cavity, the diaphragm being spaced apart from the substrate to be configured to sense an acoustic pressure to generate a corresponding displacement, an anchor completely surrounding an end portion of the diaphragm, the anchor being fixed to an upper surface of the substrate to support the diaphragm from the substrate, and a back plate disposed over the diaphragm and in the vibration area, and the back plate being spaced apart from the diaphragm to form an air gap and having a plurality of acoustic holes.

### CROSS-REFERENCE TO RELATED APPLICATION

This application claims priority to Korean Patent Application No. 10-2020-0169494 filed on Dec. 7, 2020, and all the benefits accruing therefrom under 35 U.S.C. § 119, the contents of which are incorporated by reference in their entirety.

### TECHNICAL FIELD

The present disclosure relates to a Micro Electro Mechanical Systems (MEMS) microphone and a method of manufacturing the MEMS microphone. More particularly, the present disclosure relates the MEMS microphone capable of transforming an acoustic wave into an electric signal using a displacement of a diaphragm which occurs due to an acoustic pressure, and the method of manufacturing such a MEMS microphone.

### BACKGROUND

Generally, a capacitive microphone utilizes a variable capacitance between a pair of electrodes which are facing each other to detect an acoustic signal and transform it to an electrical signal. The capacitive microphone may be manufactured by a semiconductor MEMS process such that the capacitive microphone has a MEMS type having an ultra-small size, which is referred as a MEMS microphone.

The MEMS microphone may include a substrate having a cavity, a diaphragm provided to be bendable, an anchor supporting the substrate, and a back plate provided to face the diaphragm. Further, The MEMS microphone may include a diaphragm pad being connected to the diaphragm and a back plate pad being connected to the back plate. The anchor has a slit portion as an exposed portion, and the slit may connect the diaphragm to the diaphragm pad.

An air blowing inspection may be used to test physical properties of the MEMS microphone. In the case where the anchor has a non-uniform structure due to a slit, an air pressure may be concentrated at the slit portion when the air is sprayed, and deformation or damage may occur at the slit portion. Therefore, the physical properties of the MEMS microphone may be deteriorated.

### SUMMARY

The example embodiments of the present invention provide a MEMS microphone capable of preventing the anchor from deforming or damaging while performing an air blowing inspection.

The example embodiments of the present invention provide a method of manufacturing a MEMS microphone capable of preventing the anchor from deforming or being damaged while performing an air blowing inspection.

According to an example embodiment of the present invention, a MEMS microphone includes a substrate including a vibration area defining a cavity, a supporting area surrounding the vibration area, and a peripheral area surrounding the supporting area, a diaphragm disposed over the substrate to cover the cavity, the diaphragm being spaced apart from the substrate to be configured to sense an acoustic pressure to generate a corresponding displacement, an anchor completely surrounding an end portion of the diaphragm, the anchor being fixed to an upper surface of the substrate to support the diaphragm from the substrate, and a back plate disposed over the diaphragm and in the vibration area, and the back plate being spaced apart from the diaphragm to form an air gap and having a plurality of acoustic holes.

In an example embodiment of the present invention, the MEMS microphone may further include a diaphragm pad positioned over the substrate in the supporting area, being connected to the diaphragm via the anchor.

In an example embodiment of the present invention, the MEMS microphone may further include an upper insulation layer to cover the back plate, the upper insulation layer being configured to hold the back plate to make the back plate being spaced apart from the diaphragm to define an air gap with the diaphragm, a plurality of chamber portions provided in the supporting area, spaced apart from each other along a circumference of the vibration area, each of the chamber portions having a lower surface in contact with the upper surface of the substrate to support the upper insulation layer from the substrate, a lower insulation layer provided under the upper insulation layer and on the substrate and disposed further from the vibration area than the chamber portions, and an intermediate insulation layer provided between the lower insulation layer and the upper insulation layer and disposed further from the vibration area than the chamber portions, wherein a plurality of slits is provided between the chamber portions with exposing the upper surface of the substrate and communicating with the air gap, respectively.

In an example embodiment of the present invention, the MEMS microphone may further include a back plate pad positioned on the intermediate insulation layer and electrically connected to the back plate, wherein the diaphragm pad is positioned on the lower insulation layer.

Here, the diaphragm pad and the back plate pad are connected to the diaphragm and the back plate through the slits, respectively.

In an example embodiment, the diaphragm includes a plurality of vent holes penetrating through the diaphragm and arranged apart from each other along a circumference of the diaphragm.

According to an example embodiment of the present invention, a MEMS microphone may be manufactured by forming an insulation layer on a substrate being divided into a vibration area, a supporting area surrounding the vibration area and a peripheral area surrounding the supporting area, forming a diaphragm in the vibration area and on the lower insulation layer and an anchor completely surrounding an end portion of the diaphragm, the diaphragm being fixed to an upper surface of the substrate to support the diaphragm from the substrate, forming an intermediate insulation layer on the lower insulation layer on which the diaphragm is formed, forming a back plate on the intermediate insulation layer in the vibration area, the back plate facing the diaphragm, and forming an upper insulation layer on the intermediate insulation layer for holding the back plate to make the back plate spaced apart from the diaphragm, and a plurality of chamber portions spaced apart from each other along a circumference of the vibration area for supporting the upper insulation layer from the substrate.

In an example embodiment, forming the diaphragm and the anchor may include patterning the lower insulation layer to form an anchor channel for forming the anchor in the supporting area in a ring shape, forming a first silicon layer on the lower insulation layer on which the anchor channel is formed, and patterning the first silicon layer to form the diaphragm in the vibration area and the anchor in the supporting area.

Here, forming the diaphragm and the anchor may include patterning the first silicon layer to form vent holes penetrating through the diaphragm in the vibration area at the same time when forming the diaphragm and the anchor.

Further, the vent holes serve as fluid paths for an etchant for removing the lower insulation layer and the intermediate insulation layer.

In an example embodiment of the present invention, a MEMS microphone may be manufactured by, after forming the upper insulation layer, patterning the back plate and the upper insulation layer to form acoustic holes penetrating through the back plate and the upper insulation layer, patterning the substrate to form a cavity exposing the lower insulation layer in the vibration area and performing an etching process using the cavity and the acoustic holes for completely removing the lower insulation layer and the intermediate insulation layer in both the vibration region and the support region to form an air gap between the diaphragm and the back plate, and slits between the chamber portions, communicating with the air gap.

Here, forming the diaphragm and the anchor may include patterning the first silicon layer to form a diaphragm pad in the peripheral area, being connected to the diaphragm via the anchor.

Further, the diaphragm pad may be connected to the diaphragm via a space between the chamber portions adjacent to each other.

Furthermore, forming the back plate may include forming a second silicon layer on the intermediate insulation layer, patterning the second silicon layer to form a back plate in the vibration area and a back plate pad connected to the back plate in the peripheral area.

Meanwhile, the back plate pad is connected to the back plate via a space between the chamber portions adjacent to each other.

According to embodiments of the present invention, the anchor completely surrounds the diaphragm without any slit such that the anchor has a closed structure rather than an open structure. Even when air is blown into the MEMS microphone for the air blowing inspection, the air pressure may be uniformly applied to the entire anchor. Accordingly, it is possible to prevent deformation or breakage of the MEMS microphone, thereby improving the physical properties of the MEMS microphone.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a plan view illustrating a MEMS microphone in accordance with an embodiment of the present invention;

FIG. 2 is a cross sectional view taken along a line I-I′ in FIG. 1;

FIG. 3 is a cross sectional view taken along a line II-II′ in FIG. 1;

FIG. 4 is a cross sectional view taken along a line in III-III′ FIG. 1;

FIG. 5 is a cross sectional view taken along a line IV-IV′ in FIG. 1;

FIG. 6 is a flow chart illustrating a method of manufacturing a MEMS microphone in accordance with an embodiment of the present invention; and

FIGS. 7 to 19 are cross sectional views illustrating a method of manufacturing a MEMS microphone in accordance with an embodiment of the present invention.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF EMBODIMENTS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the present invention are not limited to these terms.

Furthermore, and solely for convenience of description, elements may be referred to as “above” or “below” one another. It will be understood that such description refers to the orientation shown in the Figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

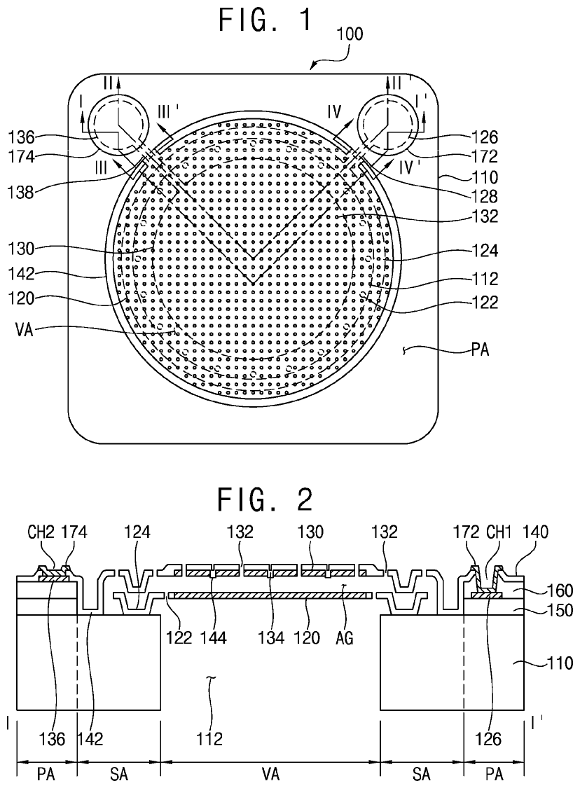

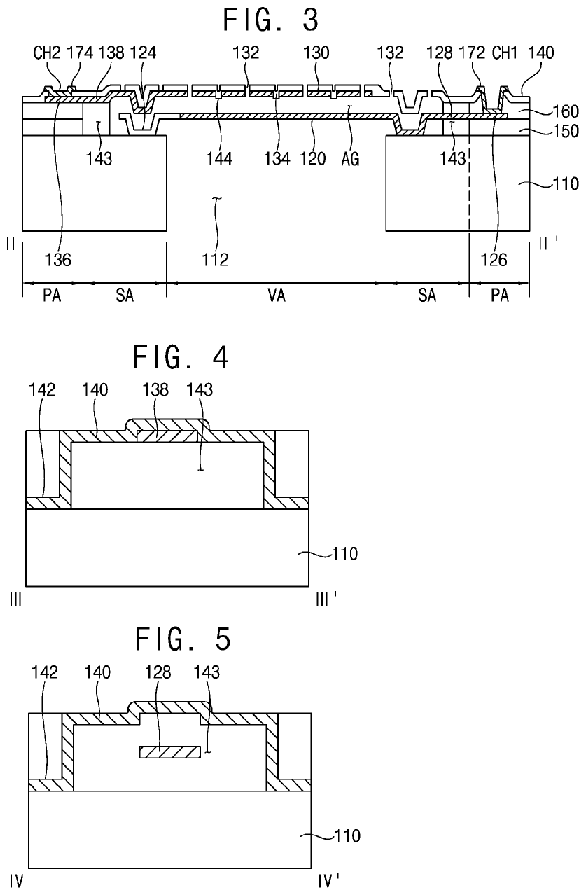

FIG. 1 is a plan view illustrating a MEMS microphone in accordance with an embodiment of the present invention. FIG. 2 is a cross sectional view taken along a line I-I′ in FIG. 1. FIG. 3 is a cross sectional view taken along a line II-II′ in FIG. 1. FIG. 4 is a cross sectional view taken along a line III-III′ in FIG. 1. FIG. 5 is a cross sectional view taken along a line IV-IV′ in FIG. 1.

Referring to FIGS. 1 to 5, a MEMS microphone 100 is capable of generating a displacement in response to an acoustic pressure to convert an acoustic signal into an electrical signal and output the electrical signal outwardly. The MEMS microphone 100 in accordance with an example embodiment of the present invention includes a substrate 110, a diaphragm 120 and a back plate 130.

The substrate 110 is divided into a vibration area VA, a supporting area SA surrounding the vibration area VA and a peripheral area PA surrounding the supporting area SA. In the vibration area VA, a cavity 112 penetrating through the substrate in a vertical direction is formed. Thus, the cavity 112 may define the vibration area VA.

For example, the cavity 112 may have a substantially ring shape, and may have a size corresponding to the vibration area VA.

The diaphragm 120 may be positioned over the substrate 110. The diaphragm 120 may have a membrane structure to cover the cavity 112. The diaphragm 120 is exposed through the cavity 112. The diaphragm 120 is spaced apart from the substrate 110 in a vertical direction and is configured to be bendable in response to an acoustic pressure.

The diaphragm 120 may have an ion implantation region into which impurities such as type III elements or type V elements are doped. The ion implantation region may correspond to the back plate 130. The diaphragm 120 may have a substantially circular shape,

In particular, the diaphragm 120 may have an end portion being connected to an anchor 124. The anchor 124 may extend along a circumference of the diaphragm 120. The anchor 124 may have a ring shape and may surround the cavity 112.

The anchor 124 may be disposed in the supporting area SA, and supports the diaphragm 120. The anchor 124 may have a complete ring shape without an interval. Accordingly, the anchor 124 has a close structure rather than an open structure. Even when air is provided into the MEMS microphone 100 for performing an air blowing inspection, an air pressure may occur uniformly to the anchor 124 entirely. Since deformation or damage of the MEMS microphone 100 is prevented, the MEMS microphone 100 may have improved physical properties.

The anchor 124 may extend from the end portion of the diaphragm 120 toward the substrate 110 to make the diaphragm 120 spaced form the substrate 110.

For example, the anchor 124 may be provided integrally with the diaphragm 120, having a lower surface in contact with an upper surface of the substrate 110.

In an example embodiment, the diaphragm 120 may have a plurality of vent holes 122. The vent holes 122 may be arranged along the anchor 124 and may be spaced apart from one another to be arranged in a ring shape.

The vent holes 122 may penetrate through the diaphragm 120 to communicate with the cavity 112. The vent holes 122 may serve as vent channels for the acoustic wave to flow. Further, the vent holes 122 may serve as fluid paths for an etchant to flow while manufacturing the MEMS microphone 110.

The vent holes 122 are positioned in the vibration area VA. Alternatively, the vent holes 122 may be arranged along a boundary between the vibration area VA and the supporting area SA or in the supporting area SA adjacent to the vibration area VA.

The back plate 130 may be positioned over the diaphragm 120. The back plate 130 may be disposed in the vibration area VA. The back plate 130 is spaced apart from the diaphragm 120 and is provided to face the diaphragm 120. Like the diaphragm 120, the back plate 130 may have a circular shape.

In an example embodiment, the MEMS microphone 110 may further include an upper insulation layer 140 and a plurality of chamber portions 142 for supporting the back plate 140 from the substrate 110.

In particular, the upper insulation layer 140 may be disposed over the substrate 110. The upper insulation layer 140 may also cover an upper surface of the back plate 130. The upper insulation layer 140 may hold the back plate 130 to make the back plate 130 spaced apart from the diaphragm 120. Thus, since the back plate 130 is spaced apart from the diaphragm 120, the diaphragm 120 may freely vibrate in response to the acoustic pressure. Further, an air gap AG may be formed between the diaphragm 120 and the back plate 130.

The back plate 130 may include a plurality of acoustic holes 132 through which the acoustic pressure passes. The acoustic holes 132 may penetrate through the back plate 130 and the upper insulation layer 140 to communicate with the air gap AG. The acoustic holes 132 may be further formed in the supporting area SA, not in the vibration area VA in which the back plate 130 is formed. The acoustic holes 132 may penetrate through the upper insulation layer 140 to communicate with the air gap AG.

The acoustic holes 132 may be disposed to be alternatively arranged with the vent holes 122 in a vertical direction. That is, the acoustic holes 132 and the vent holes 122 may not be overlapped with each other in the vertical direction. Accordingly, the acoustic wave may be prevented from being directly transmitted between the vent holes 122 and the acoustic holes 132. That is, after the acoustic wave passes through the vent holes 122, the acoustic wave may be prevented from being directly transmitted to the acoustic holes 132. Further, after the acoustic wave passes through the acoustic holes 132, the acoustic wave may be prevented from being directly transmitted to the vent holes 122.

In an example embodiment, the back plate 130 may have a plurality of dimple holes 134, and the upper insulation layer 140 may have a plurality of dimples 144 positioned to correspond to those of the dimple holes 134. The dimple holes 134 penetrate through the back plate 130, and the dimples 144 are provided at positions where the dimple holes 134 are formed.

The dimples 144 may protrude from a lower surface of the back plate 130 toward the diaphragm 120. Thus, the dimples 144 may prevent the diaphragm 120 from being coupled to the lower surface of the back plate 130.

In particular, the diaphragm 120 may be bent up and down in accordance with the acoustic pressure. A degree of bending of the diaphragm 120 varies according to a magnitude of the acoustic pressure. Even when the diaphragm 120 is severely bent (e.g., so much that the diaphragm 120 contacts the back plate 130), the dimples 144 may separate the diaphragm 120 and the back plate 130 from one another so that the diaphragm 120 may return to an initial position rather than becoming stuck in contact with one another more permanently.

The chamber portions 142 may be positioned in the supporting area SA and adjacent to the boundary between the supporting area SA and the peripheral area PA, and support the upper insulation layer 140 such that the upper insulation layer 140 and the back plate 130 are spaced apart from the diaphragm 120. The chamber portions 142 are formed by bending the upper insulation layer 140 toward the substrate 110. As shown in FIG. 2, lower surfaces of the chamber portions 142 may be disposed in contact with the upper surfaces of the substrate 110.

The chamber portions 142 are spaced outwardly apart from the diaphragm 120 and may be located outside of the anchor 124. The chamber portions 142 may be arranged to have a substantially ring shape, and may be disposed to surround the diaphragm 120.

For example, each of the chamber portions 142 may be provided integrally with the upper insulation layer 140, and may have a ‘U’-shaped longitudinal cross-section.

The chamber portions 142 may be spaced apart from each other. Slits 143 may be provided between the chamber portions 142 adjacent to each other. The slits 143 may expose the upper surface of the substrate 110 and communicate with the air gap AG.

In some embodiments, the MEMS microphone 100 may further include a lower insulation layer 150, a diaphragm pad 126, an intermediate insulation layer 160, a back plate pad 136, a first pad electrode 172 and a second pad electrode 174.

In particular, the lower insulation layer 150 may be formed on the upper surface of the substrate 110 and beneath the upper insulation layer 140. The lower insulation layer 150 may be located in the peripheral area PA and outside of the chamber portions 142.

The diaphragm pad 126 may be formed on the upper face of the lower insulation layer 150. The diaphragm pad 126 may be positioned in the peripheral area PA. The diaphragm pad 126 may be electrically connected to the diaphragm 120. The diaphragm pad 126 may be doped with impurities through ion implantation process.

A first connection portion 128 may connects the anchor 124 to the diaphragm pad 126. In this case, the diaphragm pad 126 may be connected to the diaphragm 120 via the anchor 124 and the first connection portion 128.

The intermediate insulation layer 160 may be formed on the lower insulation layer 150 having the diaphragm pad 126. The intermediate insulation layer 160 is interposed between the lower insulation layer 150 and the upper insulation layer 140, and is located in the peripheral area PA. The intermediate insulation layer 160 may be positioned outside of the chamber portions 142.

In addition, the lower insulation layer 150 and the intermediate insulation layer 160 may be formed using a material different from that of the upper insulation layer 140. For example, the upper insulation layer 140 may include a nitride such as silicon nitride, and the lower insulation layer 150 and the intermediate insulation layer 160 may include an oxide such as silicon oxide.

The back plate pad 136 is positioned in the peripheral area PA and may be provided on the upper surface of the intermediate insulation layer 160. The back plate pad 136 is electrically connected to the back plate 130 and may be doped with impurities through an ion implantation process. Although not specifically illustrated in the drawings, impurities may be doped into both the back plate pad 136 and a second connection portion 138 which connects the back plate pad 136 to the back plate 130. In this case, the second connection portion 138 may connect the back plate 130 to the back plate pad 136 through one of the slits 143. Accordingly, the second connection portion 138 may not interfere with the chamber portions 142.

A first contact hole CH1 is located in the peripheral area PA. The first contact hole CH1 penetrates through the upper insulation layer 140 and the intermediate insulation layer 160 to exposes the diaphragm pad 126.

In addition, A second contact hole CH2 is located in the peripheral area PA. The second contact hole CH2 penetrates through the upper insulation layer 140 to exposes the back plate pad 136.

The first pad electrode 172 may be provided on the diaphragm pad 138 in the peripheral area PA. Accordingly, the first pad electrode 172 may be electrically connected to the diaphragm pad 126.

The second pad electrode 174 may be positioned above the back plate pad 136 in the peripheral area PA and may be electrically connected to the back plate pad 136.

As described above, the MEMS microphone 100 may include the anchor 124 having a complete ring shape without a slit. Accordingly, the anchor 124 has a closed structure rather than an open structure. Even when the air is sprayed by the MEMS microphone 100, the air pressure may be uniformly applied to the entire anchor 124. Since deformation or damage of the MEMS microphone 100 due to the air pressure is prevented, physical properties of the MEMS microphone 100 may be improved.

Hereinafter, a method of manufacturing a MEMS microphone will be described in detail with reference to the drawings.

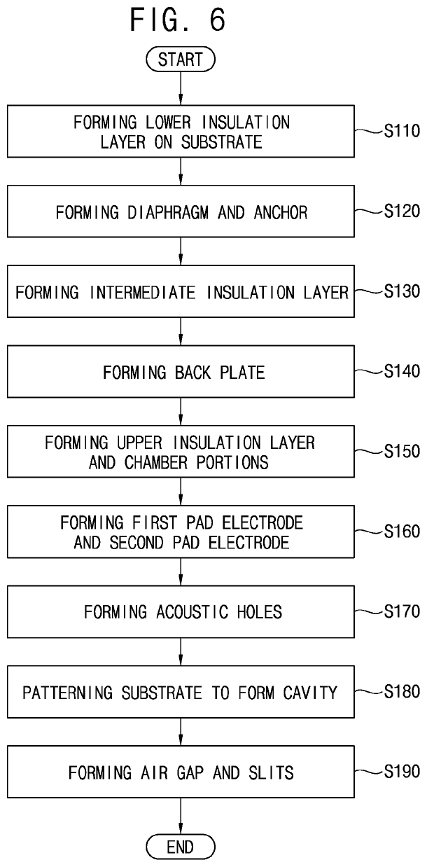

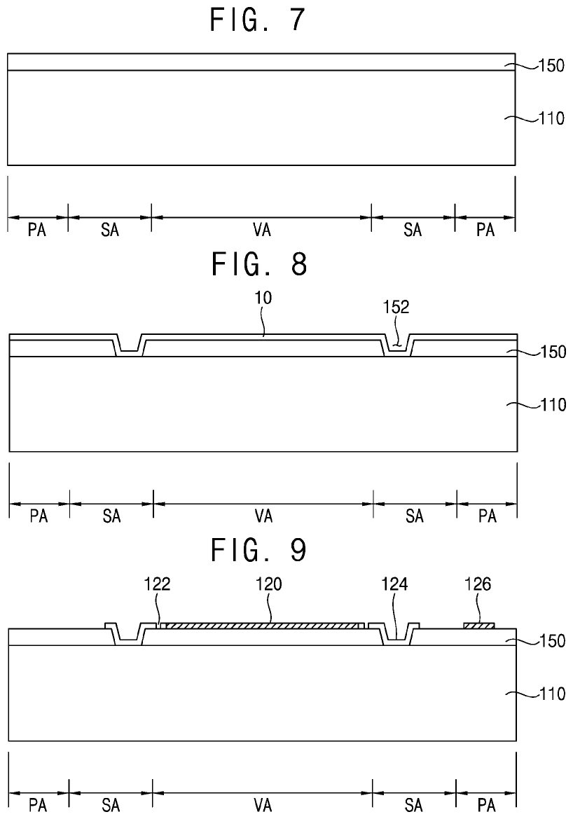

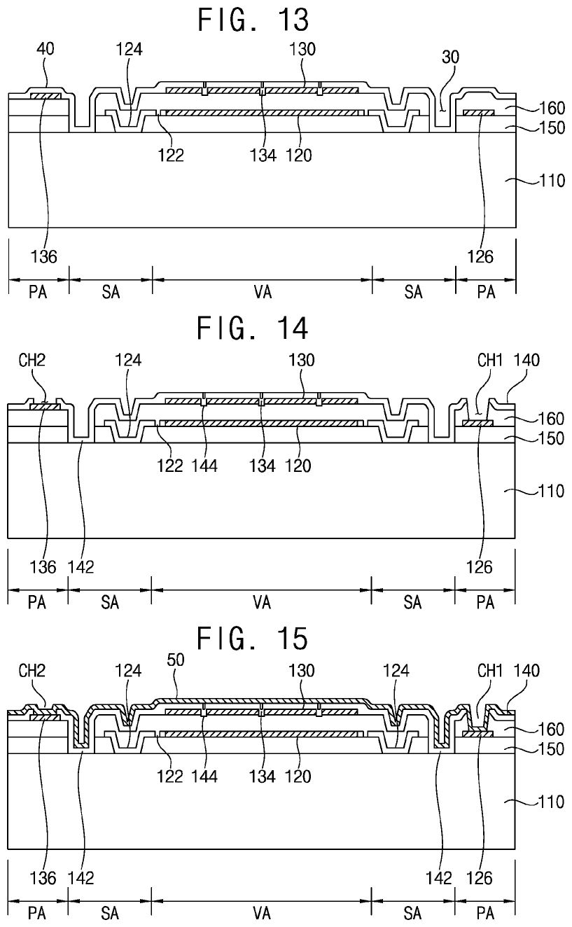

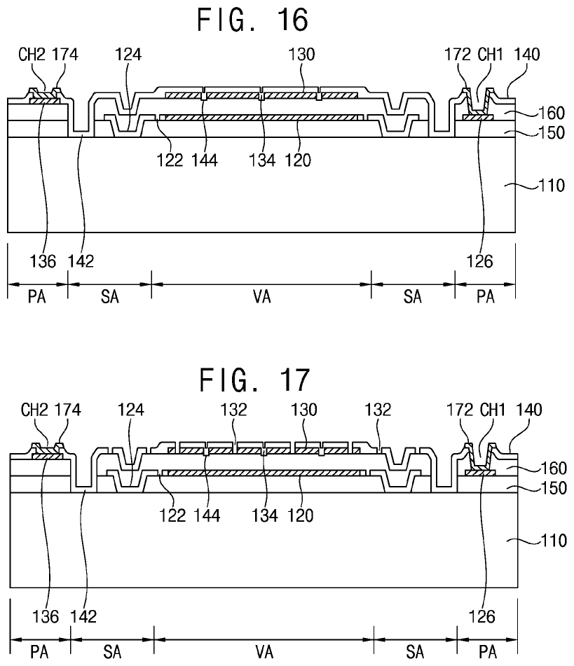

FIG. 6 is a flow chart illustrating a method of manufacturing a MEMS microphone in accordance with an embodiment of the present invention. FIGS. 7 to 19 are cross sectional views illustrating a method of manufacturing a MEMS microphone in accordance with an embodiment of the present invention.

Referring to FIGS. 6 and 7, according to an example embodiment of a method for manufacturing a MEMS microphone, a lower insulation layer 150 is formed on a substrate 110 (at S110).

The lower insulation layer 150 may be formed through a deposition process. The lower insulation layer 150 may be formed using an oxide such as a silicon oxide.

Referring to FIGS. 6, 8 and 9, a diaphragm 120, an anchor 124 and a diaphragm pad 126 are formed on the lower insulation layer 150 (at S120).

The diaphragm 120, the anchor 124 and the diaphragm pad 126 are formed by the subsidiary steps as illustrated in detail as below.

Firstly, the lower insulation layer 150 is patterned by an etching process to form an anchor channel 152 for forming the anchor 124 to partially expose a lower surface of the substrate 110. The anchor channel 152 is formed at a supporting area SA of the substrate 110. For example, the anchor channel 152 has a ring shape of completely surrounding a vibration area VA.

Then, a first silicon layer 10 is formed on the lower insulation layer 150 having the anchor channel 152. For example, the first silicon layer 10 may be formed using polysilicon.

An ion implanting process is then performed to dope impurities into both the vibration area VA of the first silicon layer 10 and a portion of the first silicon layer 10, corresponding to a position of a diaphragm pad 126.

The first silicon layer 10 is patterned by an etch process to form the diaphragm 120 and the anchor 124, Further, a diaphragm pad 126 may be formed on the lower insulation layer 150 and in a peripheral area PA. A first connection portion 128 may connects the anchor 124 to the diaphragm pad 126. The diaphragm pad 126 may be connected to the diaphragm 120 via the anchor 124 and the first connection portion 128. The first connection portion 128 and the anchor 124 may also be doped with impurities.

In an example embodiment, the anchor 124 may be formed in a pattern of a ring shape along a circumference of the diaphragm 120 to entirely surround the diaphragm 120. Accordingly, the diaphragm pad 126 may be connected to the diaphragm 120 through the anchor 124 and the first connection portion 128.

The anchor 124 has a complete ring shape to have a close structure rather than an open structure. Even when air is provided into the MEMS microphone 100 for performing an air blowing inspection, an air pressure may be uniformly applied to the anchor 124 entirely. Since deformation or damage of the MEMS microphone 100 is prevented, the MEMS microphone 100 may have improved physical properties.

When the diaphragm 120, the anchor 124 and the diaphragm pad 126 are formed, a plurality of vent holes 122 may also be formed by penetrating through the diaphragm 120. The vent holes 122 are located in the vibration area VA. The vent holes 122 are spaced apart from each other along the anchor 124 and may be arranged in a pattern of a ring shape.

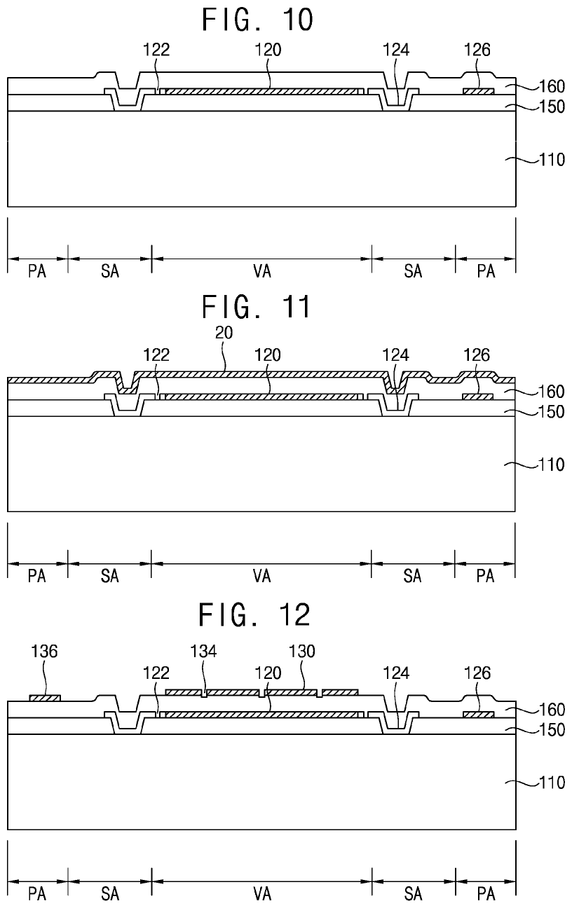

Referring to FIGS. 6 and 10, the intermediate insulation layer 160 is formed on the lower insulation layer 150 on which the diaphragm 120, the vent holes 122, the anchor 124 and the diaphragm pad 126 are formed (at S130).

The intermediate insulation layer 160 may be formed by a deposition process. The intermediate insulation layer 160 may be formed using a material identical to that of the lower insulation layer 150. For example, the intermediate insulation layer 160 is formed using an oxide such as silicon oxide or tetraethyl orthosilicate (TEOS).

The intermediate insulation layer 160 may fill the vent holes 122. Accordingly, the vent holes 122 may be filled with the oxide.

FIGS. 6, 11 and 12, a back plate 130 and a back plate pad 136 are formed on the intermediate insulation layer 160 (at S140).

First, a second silicon layer 20 is deposited on an upper surface of the intermediate insulation layer 160 and then impurities are doped into the second silicon layer 20 through an ion implantation process. For example, the second silicon layer 20 may be made of polysilicon.

The second silicon layer 20 is patterned to form dimple holes 134 for forming dimples 144(refer to FIG. 2). The dimple holes 134 may be formed in the vibration area VA. Specifically, the dimple holes 114 may be provided in a region where the back plate 130 is to be formed. A portion of the intermediate insulation layer 160 corresponding to the dimple hole 134 may be partially etched so that the dimples 144 protrude from a lower surface of the back plate 130 downwardly.

Next, the second silicon layer 20 is patterned to form the back plate 130 and the back plate pad 136. The back plate 130 may be formed in the vibration area VA, and the back plate pad 136 may be formed in the peripheral area PA. In this case, a second connection portion 138 may connect the back plate 130 and the back plate pad 136 to each other (see FIG. 1).

Referring to FIGS. 6, 13 and 14, an upper insulation layer 140 and chamber portions 142 are formed on the intermediate insulation layer 160 on which the back plate 130 and the back plate pad 136 are formed (at S150).

Specifically, the intermediate insulation layer 160 and the lower insulation layer 150 are patterned through an etching process to form chamber channels 30 for forming chamber portions 142 (see FIG. 2) in the supporting area SA. The substrate 110 may be partially exposed through the chamber channels 30. Although not specifically illustrated in the drawings, the chamber channels 30 may be spaced apart from each other, and the chamber channels 30 are arranged to have a substantially ring shape to surround the diaphragm 120. Also, the first connection porting 128 and the second connection portion 138 may be positioned between the chamber channels 30.

After depositing an insulation layer 40 on the intermediate insulation layer 160 on which the chamber channels 30 are formed, the insulation layer 40 is patterned to form the upper insulation layer 140 and the chamber portions 142. The chamber portions 142 may be spaced apart from each other and may be arranged to have a substantially ring shape.

Further, the dimples 144 are formed in the dimple holes 134 while depositing the insulation layer 40 on the intermediate insulation layer 160.

By patterning the insulation layer 40, a second contact hole CH2 is formed in the peripheral area PA to expose the back plate pad 136. Then, portions of the insulation layer 40 and the intermediate insulation layer 160, which face the upper surface of the diaphragm pad 126, are removed to form the first contact hole CH1. The diaphragm pad 126 is exposed through the first contact hole CH1.

The upper insulation layer 140 may be made of a material different from those of the lower insulation layer 150 and the intermediate insulation layer 160. For example, the upper insulation layer 140 may be made of a nitride such as silicon nitride, and the lower insulation layer 150 and the intermediate insulation layer 160 may be made of the oxide.

FIGS. 6, 15 and 16, a first pad electrode 172 and a second pad electrode 174 are formed in the first contact hole CH1 and the second contact holes CH2 in the peripheral area PA (at S160).

Specifically, a thin layer 50 is deposited on the upper insulation layer 140 in which the first contact hole CH1 and the second contact holes CH2 are formed. Here, the thin layer 50 may be made of a conductive metal material.

The thin layer 50 is patterned to form the first pad electrode 172 and the second pad electrode 174. In this case, the first pad electrode 172 may be formed on the diaphragm pad 126, and the second pad electrode 174 may be formed on the back plate pad 136.

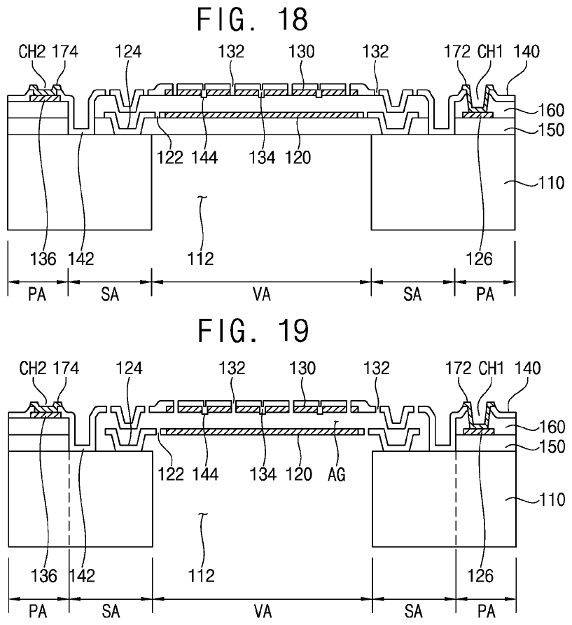

Referring to FIGS. 6 and 17, the upper insulation layer 140 and the back plate 130 are patterned to form acoustic holes 132 (at S170).

The acoustic holes 132 may be formed by penetrating through both the upper insulation layer 140 and the back plate 130 in the vibration area VA. Further, in the supporting area SA, the acoustic holes 132 may be formed to penetrate through only the upper insulation layer 140. Each of the acoustic holes 132 may have various shapes, such as a circular shape and a polygonal shape, etc.

In an example embodiment, the acoustic holes 132 may be disposed to be alternatively arranged with the vent holes 122. That is, the acoustic holes 132 and the vent holes 122 may not be vertically overlapped with one another in a vertical direction. Accordingly, the acoustic wave may be prevented from being directly transmitted between the vent holes 122 and the acoustic holes 132. That is, after the acoustic wave passes through the vent holes 122, the acoustic wave may be prevented from being directly transmitted to the acoustic holes 132. Further, after the acoustic wave passes through the acoustic holes 132, the acoustic wave may be prevented from being directly transmitted to the vent holes 122.

FIGS. 6 and 18, after the acoustic holes 132 are formed, the substrate 110 is patterned to form a cavity 112 in the vibration area VA. (at S180).

The lower insulation layer 150 is partially exposed through the cavity 112.

FIGS. 6 and 19, through an etching process using the cavity 112, the first acoustic holes 132, the second acoustic holes 146 and the vent holes 122, the lower insulation layer 150 and the intermediate insulation layer 160 are removed completely from both the vibration area VA and the supporting area SA, and partially from the peripheral area PA to form an air gap AG between the diaphragm 120 and the back plate 130, a plurality of slits 143 between the chamber portions 142 adjacent to each other, communicating with the air gap AG (at S190).

Specifically, the cavity 112, the acoustic holes 132 and the vent holes 122 may be provided as fluid paths of the etchant for removing the lower insulation layer 150 and the intermediate insulation layer 160.

Meanwhile, the anchor 124 and the chamber portions 142 serve to limit the flow area of the etchant.

For example, hydrogen fluoride vapor (HF vapor) may be used as the etchant for removing the intermediate insulation layer 160 and the lower insulation layer 150.

The lower insulation layer 150 and the intermediate insulation layer 160 from the vibration area VA and the support area SA are entirely removed to expose the diaphragm 120 through the cavity 112, and the air gap AG between the diaphragm 120 and the back plate 130, and the slits 143 between the chamber portions 142 adjacent to each other.

Since the first connection portion 128 and the second connection portion 138 communicate with the slits 143, the first connection portion 128 and the second connection portion 138 may not interfere with the chamber portions 142 (see FIGS. 4 and 5).

As described above, the MEMS microphone 100 may include the anchor 124 having a complete ring shape without a slit. Accordingly, the anchor 124 has a closed structure rather than an open structure. Even when the air is sprayed by the MEMS microphone 100, the air pressure may be uniformly applied to the entire anchor 124. Since deformation or damage of the MEMS microphone 100 due to the air pressure is prevented, physical properties of the MEMS microphone 100 may be improved.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A MEMS microphone comprising:
a substrate including:
a vibration area defining a cavity,
a supporting area surrounding the vibration area, and
a peripheral area surrounding the supporting area;
a diaphragm disposed over the substrate to cover the cavity, the diaphragm being spaced apart from the substrate to be configured to sense an acoustic pressure to generate a corresponding displacement;
an anchor completely surrounding an end portion of the diaphragm, the anchor being fixed to an upper surface of the substrate to support the diaphragm from the substrate; and
a back plate disposed over the diaphragm and in the vibration area, and the back plate being spaced apart from the diaphragm to form an air gap and having a plurality of acoustic holes.

2. The MEMS microphone of claim 1, further comprising:
a diaphragm pad positioned over the substrate in the supporting area, being connected to the diaphragm via the anchor.

3. The MEMS microphone of claim 2, further comprising:
an upper insulation layer to cover the back plate, the upper insulation layer being configured to hold the back plate to make the back plate being spaced apart from the diaphragm to define an air gap with the diaphragm;
a plurality of chamber portions provided in the supporting area, spaced apart from each other along a circumference of the vibration area, each of the chamber portions having a lower surface in contact with the upper surface of the substrate to support the upper insulation layer from the substrate,
a lower insulation layer provided under the upper insulation layer and on the substrate and disposed further from the vibration area than the chamber portions; and
an intermediate insulation layer provided between the lower insulation layer and the upper insulation layer and disposed further from the vibration area than the chamber portions,
wherein a plurality of slits is provided between the chamber portions with exposing the upper surface of the substrate and communicating with the air gap, respectively.

4. The MEMS microphone of claim 3, further comprising a back plate pad positioned on the intermediate insulation layer and electrically connected to the back plate,
wherein the diaphragm pad is positioned on the lower insulation layer.

5. The MEMS microphone of claim 4, wherein the diaphragm pad and the back plate pad are connected to the diaphragm and the back plate through the slits, respectively.

6. The MEMS microphone of claim 1, wherein the diaphragm includes a plurality of vent holes penetrating through the diaphragm, and spaced apart from each other along a circumference of the diaphragm.

7. A method of manufacturing a MEMS microphone comprising:
forming an insulation layer on a substrate being divided into a vibration area, a supporting area surrounding the vibration area and a peripheral area surrounding the supporting area;
forming a diaphragm in the vibration area and on the lower insulation layer and an anchor completely surrounding an end portion of the diaphragm, the diaphragm being fixed to an upper surface of the substrate to support the diaphragm from the substrate;
forming an intermediate insulation layer on the lower insulation layer on which the diaphragm is formed;
forming a back plate on the intermediate insulation layer in the vibration area, the back plate facing the diaphragm; and
forming an upper insulation layer on the intermediate insulation layer for holding the back plate to make the back plate spaced apart from the diaphragm, and a plurality of chamber portions spaced apart from each other along a circumference of the vibration area for supporting the upper insulation layer from the substrate.

8. The method of claim 7, wherein forming the diaphragm and the anchor comprises:
patterning the lower insulation layer to form an anchor channel for forming the anchor in the supporting area in a ring shape;
forming a first silicon layer on the lower insulation layer on which the anchor channel is formed; and
patterning the first silicon layer to form the diaphragm in the vibration area and the anchor in the supporting area.

9. The method of claim 8, wherein forming the diaphragm and the anchor comprises patterning the first silicon layer to form vent holes penetrating through the diaphragm in the vibration area at the same time when forming the diaphragm and the anchor.

10. The method of claim 9, wherein the vent holes serve as fluid paths for an etchant for removing the lower insulation layer and the intermediate insulation layer.

11. The method of claim 7, further comprising:
after forming the upper insulation layer,
patterning the back plate and the upper insulation layer to form acoustic holes penetrating through the back plate and the upper insulation layer;
patterning the substrate to form a cavity exposing the lower insulation layer in the vibration area; and
performing an etching process using the cavity and the acoustic holes to completely remove the lower insulation layer and the intermediate insulation layer in both the vibration region and the support region to form an air gap between the diaphragm and the back plate, and slits between the chamber portions communicating with the air gap.

12. The method of claim 11, wherein forming the diaphragm and the anchor comprises patterning the first silicon layer to form a diaphragm pad in the peripheral area, the diaphragm pad connected to the diaphragm via the anchor.

13. The method of claim 12, wherein the diaphragm pad is connected to the diaphragm via a space between the chamber portions adjacent to each other.

14. The method of claim 11, wherein forming the back plate comprises:
forming a second silicon layer on the intermediate insulation layer; and
patterning the second silicon layer to form a back plate in the vibration area and a back plate pad connected to the back plate in the peripheral area.

15. The method of claim 14, wherein the back plate pad is connected to the back plate via a space between the chamber portions adjacent to each other.
